(19) United States
(12) Patent Application Publication
(10) Pub. No.: US 2016/0223722 A1
(43) Pub. Date: Aug. 4, 2016

(54) DISPLAY DEVICE AND METHOD OF MANUFACTURING THE SAME

(71) Applicant: Samsung Display Co., Ltd., Yongin-Si (KR)

(72) Inventor: Sung Sang Ahn, Hwaseong-si (KR)

(21) Appl. No.: 14/836,773

(22) Filed: Aug. 26, 2015

(30) Foreign Application Priority Data
Feb. 3, 2015 (KR) 10-2015-0016957

(51) Int. Cl. G02B 5/00; G02B 1/14; G02B 5/30; H01L 27/12

(52) U.S. Cl. CPC G02B 5/003; H01L 27/1214; G02B 1/14; G02B 5/3083

(57) ABSTRACT

Disclosed herein is a display device, including; a display substrate; a display element layer formed on the display substrate and including a plurality of pixels; a window layer formed on the display element layer; a first light shielding printing layer formed at an edge portion of an upper surface of the window layer to shield incident light; a second light shielding printing layer formed at an edge portion of a lower surface of the window layer to shield incident light; and a hard coating layer hard-coated to cover and protect the first light shielding printing layer and the window layer.

### CROSS-REFERENCE TO RELATED APPLICATIONS

Any and all applications for which a foreign or domestic priority claim is identified in the Application Data Sheet and any amendment thereto as filed with the present application are hereby incorporated by reference under 37 CFR 1.57.

This application claims priority to and the benefit of Korean Patent Application No. 10-2015-0016957 filed in the Korean Intellectual Property Office on Feb. 3, 2015, the entire contents of which are incorporated herein by reference.

### BACKGROUND

1. Field

The described technology relates generally to a display device and a method of manufacturing the same, and more particularly, to a display device in which a light shielding printing layer is formed on a window layer and a method of manufacturing the same.

2. Description of the Related Technology

Currently, a typical display device has a structure in which a cover window is bonded to the front surface of a display panel. In the bonding structure of the display panel and the cover window, a transparent cover window is bonded on a display area of a flat display panel and an outside of the display panel needs to be provided with a region through which a driving wiring passes, and a dead space in addition to an actually driven display area is generated and the cover window needs to be provided with a minimum bezel region so as not to expose the dead space on the front surface of the display panel.

The bezel region is provided with a light shielding printing layer which is generally manufactured by being printed in black ink to shield light incident from the outside. In this case, a thickness of the light shielding printing layer needs to be thick enough to effectively shield light. Further, the display panel is attached to a lower portion of the light shielding printing layer with an adhesive such as a pressure sensitive adhesive (PSA). In this case, a step is formed between the light shielding printing layer and the cover window due to the thickness of the light shielding printing layer itself and vapor, foreign matters, and the like are trapped in the step portion to cause defects in the display of the display device.

The above information disclosed in this Background section is only for enhancement of understanding of the background of the described technology and therefore it may contain information that does not form the prior art that is already known in this country to a person of ordinary skill in the art.

### SUMMARY OF CERTAIN INVENTIVE ASPECTS

The present disclosure provides a display device and a method of manufacturing the same having advantages of reducing display defects by forming a light shielding printing layer of a bezel region on upper and lower portions of a window layer or an upper portion of the window layer to reduce a step between an adhesive and a display panel.

An exemplary embodiment provides a display device, including; a display substrate; a display element layer formed on the display substrate and including a plurality of pixels; a window layer formed on the display element layer; a first light shielding printing layer formed at an edge portion of an upper surface of the window layer to shield incident light; and a hard coating layer hard-coated to cover and protect the first light shielding printing layer and the window layer and having stiffness larger than that of the window layer.

The first light shielding printing layer may have a thickness of 20 μm to 30 μm.

The display device may further include: a thin film encapsulation layer formed on the display element layer to cover and protect the display substrate and the display element layer.

The display device may further include: a functional layer formed between the thin film encapsulation layer and the window layer,

The functional layer may be formed of a phase delay film.

The functional layer may be formed of a polarizer.

The window layer may be made of polyimide (PI) or polyethylene terephthalate (PET).

The hard coating layer may have a thickness of 40 μm to 60 μm.

The display device may further include: a second light shielding printing layer formed at an edge portion of a lower surface of the window layer to shield the incident light.

The first light shielding printing layer and the second light shielding printing layer may have a thickness of 20 μm to 30 μm.

Another embodiment provides a method of manufacturing a display device, including: forming a first light shielding printing layer at an edge portion of an upper surface of a window layer; forming a hard coating layer having stiffness larger than that of the window layer to cover the window layer and the first light shielding printing layer; and attaching a display panel to the window layer using an adhesive layer.

Still another embodiment provides a method of manufacturing a display device, including: forming a first light shielding printing layer at an edge portion of an upper surface of a window layer; forming a hard coating layer having stiffness larger than that of the window layer to cover the window layer and the first light shielding printing layer; forming a second light shielding printing layer at the edge portion of a lower surface of the window layer; and attaching a display panel to the second light shielding printing layer using an adhesive layer.

According to the exemplary embodiments, it is possible to reduce the display defects of the display device by forming the light shielding printing layer of the bezel region on the upper and lower portions of the window layer or the upper portion of the window layer to reduce the step between the adhesive and the display panel.

### BRIEF DESCRIPTION OF THE DRAWINGS

FIG. 1 is a cross-sectional view schematically illustrating a display device according to an exemplary embodiment.

FIG. 2 is a flow chart illustrating a method of manufacturing a display device according to an exemplary embodiment.

FIGS. 3A to 3D are process cross-sectional views of the method of manufacturing a display device according to the exemplary embodiment.

FIG. 4 is a cross-sectional view schematically illustrating a display device according to another exemplary embodiment.

### DETAILED DESCRIPTION

As the disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure. As used herein, the term “and/or” includes any and all combinations of one or more of the associated listed items.

Embodiments of the present disclosure will be described below in more detail with reference to the accompanying drawings. Those components that are the same or are in correspondence are rendered the same reference numeral regardless of the figure number, and redundant explanations are omitted.

It will be understood that although the terms “first”, “second”, etc. may be used herein to describe various components, these components should not be limited by these terms. These components are only used to distinguish one component from another. As used herein, the singular forms “a,” “an” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components.

In the drawings, the thickness of layers, films, panels, regions, etc., are exaggerated for explanation. In other words, since sizes and thicknesses of components in the drawings are arbitrarily illustrated for convenience of explanation, the following embodiments are not limited thereto. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

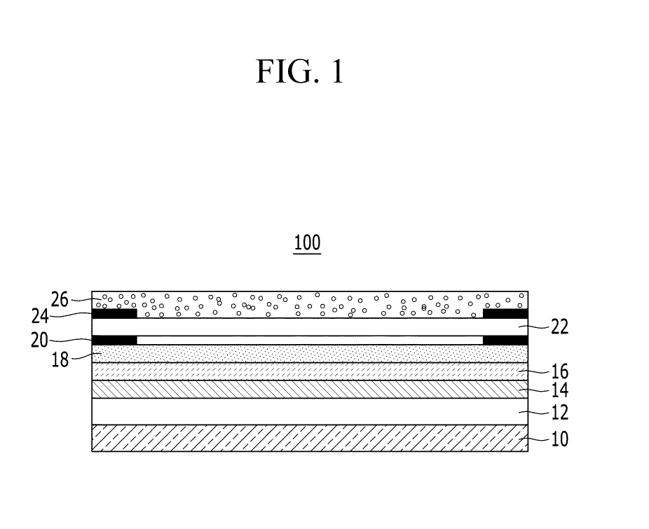

Hereinafter, a display device according to an exemplary embodiment will be described with reference to FIG. 1.

FIG. 1 is a cross-sectional view schematically illustrating a display device 100 according to an exemplary embodiment. Referring to FIG. 1, the display device 100 includes a display substrate 10, a display element layer 12 formed on the display substrate 10, a window layer 22 formed on the display element layer 12, a first light shielding printing layer 24 formed at an edge portion of an upper surface of the window layer 22 to shield incident light, a second light shielding printing layer 20 formed at an edge portion of a lower surface of the window layer 22 to shield the incident light, and a hard coating layer 26 hard-coated to cover and protect the first light shielding printing layer 24 and the window layer 22.

The display substrate 10 may be a liquid crystal display panel which includes a liquid crystal or an organic light emitting panel which includes an organic emission unit. Further, the display substrate 10 is a transparent substrate and may be a flexible substrate such as a polymer film.

The display element layer 12 is formed on the display substrate 10 and includes an element region in which an active element such as a thin film transistor (TFT) is formed and an emission region in which an emission layer is formed. The element region and the emission region may also be positioned while being separated from each other and may also be positioned while overlapping each other.

Meanwhile, the display substrate 10 and the thin film encapsulation layer 14 covering and protecting the display element layer 12 may be further provided on the display element layer 12.

The thin film encapsulation layer 14 is formed on the display element layer 12 and faces the display substrate 10. The thin film encapsulation layer 14 may prevent oxygen and moisture from inflowing from the outside to protect the display element layer 12.

The window layer 22 is formed on the thin film encapsulation layer 14 and may be made of polyimide (PI) or polyethylene terephthalate (PET). The window layer 22 may be attached to the thin film encapsulation layer 14 by an adhesive layer 18 such as a pressure sensitive adhesive (PSA).

The first light shielding printing layer 24 is formed on the edge portion of the upper surface of the window layer 22, that is, the bezel region. The first light shielding printing layer 24 is printed in black ink and may shield light incident from the outside. The first light shielding printing layer 24 may have a thickness of about 20 μm to 30 μm.

The second light shielding printing layer 20 may be formed to vertically overlap an edge portion of the lower surface of the window layer 22, that is, a formation region of the first light shielding printing layer 24. The second light shielding printing layer 20 may have a thickness of about 20 μm to 30 μm.

The hard coating layer 26 is a layer which covers and protects the second light shielding printing layer 20 and the window layer 22. The hard coating layer 26 may have a thickness of 40 μm to 60 μm. The hard coating layer 26 is made of materials having scratch resistance and wear resistance to prevent defects such as scratch, crack, and the like from occurring on the window layer 22 made of a plastic material. The hard coating layer 26 may have stiffness larger than that of the window layer. The hard coating layer 26 may be formed by coating and drying, for example, a composition for hard coating including acrylate oligomer and monomer on the upper surface of the window layer 22 and curing the composition with ultraviolet rays.

Meanwhile, the functional layer 16 may be further provided between the thin film encapsulation layer 14 and the window layer 22. The functional layer 16 may be formed of a phase delay film. The phase delay film may be a λ/4 phase delay film and serve to convert linear polarization into circular polarization or the circular polarization into the linear polarization. As the phase delay film, there can be a birefringence film which is made by performing stretching treatment to a film made of suitable polymers such as polycarbonate or polyvinyl alcohol, polystyrene or polymethyl methacrylate, polypropylene or other polyolefin, and polyarylate or polyamide, an oriented film of a liquid crystal polymer, a film supporting an oriented layer of a liquid crystal polymer, and the like. Further, the phase delay film may be made of zeonor resin or arton.

Further, the functional layer 16 may be made of polarizer. The polarizer may reduce the thickness and improve the image visibility, while securing the flexible characteristics.

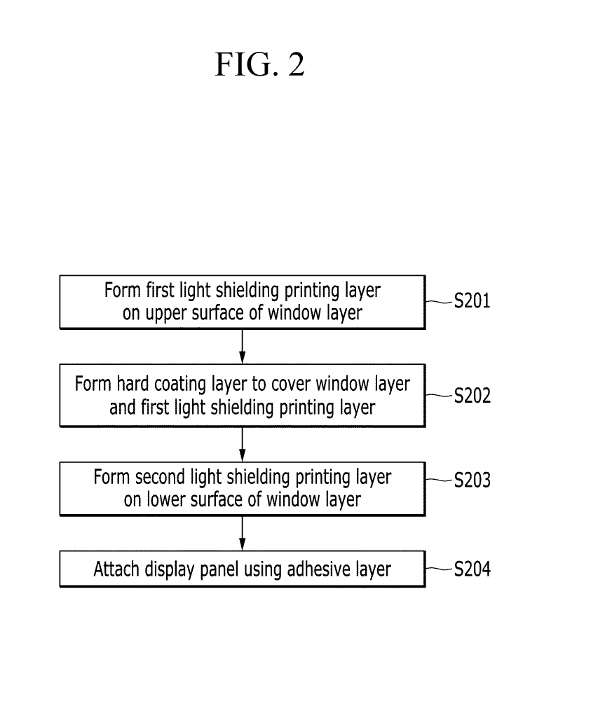

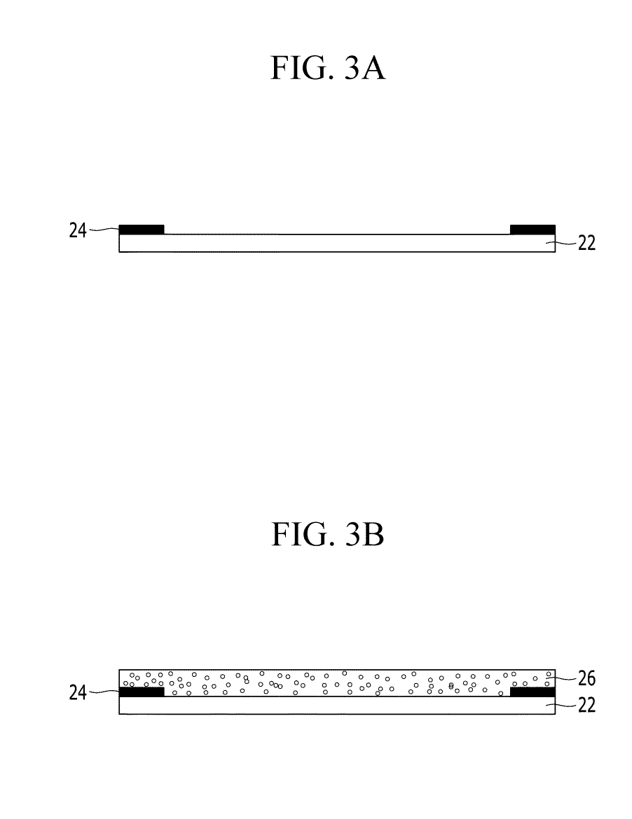

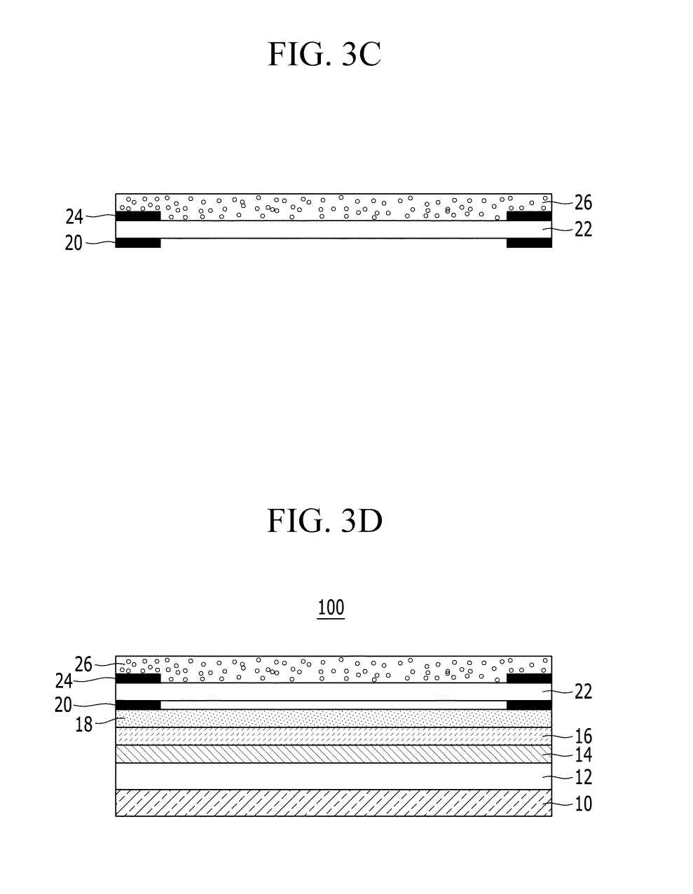

FIG. 2 is a flow chart illustrating a method of manufacturing a display device according to an exemplary embodiment and FIGS. 3A to 3D are process cross-sectional views of the method of manufacturing a display device according to the exemplary embodiment.

Referring to FIGS. 2 to 3D, first, the first light shielding printing layer 24 is formed on the edge portion of the upper surface of the window layer 22 (S201, FIG. 3A). The window layer 22 may be made of polyimide (PI) or polyethylene terephthalate (PET). The first light shielding printing layer 24 may be printed in black ink and is formed to have a thickness of about 20 μm to 30 μm.

Next, the hard coating layer 26 is formed to cover the window layer 22 and the first light shielding printing layer 24 (S202, FIG. 3B). The hard coating layer 26 may be formed by supplying a composition for hard coating, coating and drying the composition by spin coating, screen printing, inkjet, one drop filling (ODF) or a combination thereof, and curing the composition with ultraviolet rays. In addition, the composition may be cured by natural curing, heat curing, plasma curing, pressurization and humidification curing, or a combination thereof.

Next, the second light shielding printing layer 20 is formed at the edge portion of the lower surface of the window layer 22 (S203, FIG. 3C). The second light shielding printing layer 20 may be formed at the same material and thickness as the first light shielding printing layer 24 to vertically overlap the formation region of the first light shielding printing layer 24.

Next, the display panel is attached to the second light shielding printing layer 20 using the adhesive layer 18 (S204, FIG. 3D). The display panel includes layers such as the display substrate 10, the display element layer 12, the thin film encapsulation layer 14, and the like, which are illustrated in FIG. 1. The adhesive layer 18 may be made of a pressure sensitive adhesive and is formed to have a structure in which the window layer 22 covers the upper surfaces of the second light shielding printing layer 20 and the display panel.

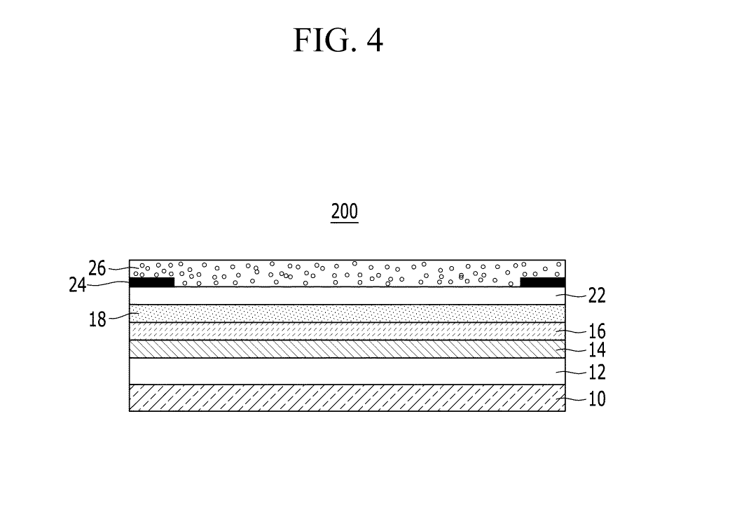

FIG. 4 is a cross-sectional view schematically illustrating a display device according to another exemplary embodiment. Referring to FIG. 4, the display device has a structure in which the second light shielding printing layer 20 is omitted in the display device 100 illustrated in FIG. 1. The second light shielding printing layer 20 is omitted, and as a result, an adhesion between the window layer 22 and the display panel may be improved and the thickness of the light shielding printing layer of the bezel region may be more reduced.

As illustrated in FIG. 4, the display device according to the exemplary embodiment includes the display substrate 10, the display element layer 12 formed on the display substrate 10 and including a plurality of pixels, the thin film encapsulation layer 14 covering and protecting the display substrate 10 and the display element layer 12, the window layer 22 formed on the thin film encapsulation layer 14, the first light shielding printing layer 24 formed at the edge portion of the upper surface of the window layer 22 to shield the incident light, and the hard coating layer 26 hard-coated to cover and protect the first light shielding printing layer 24 and the window layer 22.

In the display device according to the exemplary embodiment, the first light shielding printing layer 24 may have a thickness of 20 μm to 30 μm.

The display device according to the exemplary embodiment may further include the functional layer 16 which is formed between the thin film encapsulation layer 14 and the window layer 22.

Meanwhile, the method of manufacturing a display device according to the exemplary embodiment illustrated in FIG. 4 includes forming the first light shielding printing layer 24 at the edge portion of the upper surface of the window layer 22, forming the hard coating layer 26 to cover the window layer 22 and the first light shielding printing layer 24, and attaching the display panel to the window layer 22 using the adhesive layer 18. The method of manufacturing a display device according to the exemplary embodiment is the same as the method of manufacturing a display device described with reference to FIGS. 3A to 3D except for the forming of the second light shielding printing layer 20 and therefore the description thereof will be omitted.

As described above, according to the display device and the method of manufacturing the same according to the exemplary embodiments, it is possible to reduce the display defects of the display device by forming the light shielding printing layer of the bezel region on the upper and lower portions of the window layer 22 or the upper portion of the window layer 22 to reduce the step between the adhesive and the display panel.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present disclosure have been described with reference to the figures, it will be understood by those of ordinary skill in the art that various changes in form and details may be made therein without departing from the spirit and scope of the present disclosure as defined by the following claims.

What is claimed is:

1. A display device, comprising;
a display substrate;
a display element layer formed on the display substrate and including a plurality of pixels;
a window layer formed on the display element layer;
a first light shielding printing layer formed at an edge portion of an upper surface of the window layer to shield incident light; and
a hard coating layer hard-coated to cover and protect the first light shielding printing layer and the window layer and having stiffness larger than that of the window layer.

2. The display device of claim 1, wherein:
the first light shielding printing layer has a thickness of 20 μm to 30 μm.

3. The display device of claim 1, further comprising:
a thin film encapsulation layer formed on the display element layer to cover and protect the display substrate and the display element layer.

4. The display device of claim 3, further comprising:
a functional layer formed between the thin film encapsulation layer and the window layer.

5. The display device of claim 4, wherein:
the functional layer is formed of a phase delay film.

6. The display device of claim 4, wherein:
the functional layer is formed of a polarizer.

7. The display device of claim 1, wherein:
the window layer is a plastic substrate made of polyimide (PI) or polyethylene terephthalate (PET).

8. The display device of claim 1, wherein:
the hard coating layer has a thickness of 40 μm to 60 μm.

9. The display device of claim 1, further comprising:
a second light shielding printing layer formed at an edge portion of a lower surface of the window layer to shield the incident light.

10. The display device of claim 9, wherein:
the first light shielding printing layer and the second light shielding printing layer have a thickness of 20 μm to 30 μm.

11. A method of manufacturing a display device, comprising:
forming a first light shielding printing layer at an edge portion of an upper surface of a window layer;
forming a hard coating layer having stiffness larger than that of the window layer to cover the window layer and the first light shielding printing layer; and
attaching a display panel to the window layer using an adhesive layer.

12. A method of manufacturing a display device, comprising:
forming a first light shielding printing layer at an edge portion of an upper surface of a window layer;
forming a hard coating layer having stiffness larger than that of the window layer to cover the window layer and the first light shielding printing layer;
forming a second light shielding printing layer at an edge portion of a lower surface of the window layer; and
attaching a display panel to the second light shielding printing layer using an adhesive layer.
